(19) United States
(12) Patent Application Publication
(10) Pub. No.: US 2013/0199929 A1
(43) Pub. Date: Aug. 8, 2013

(54) COATING SOURCE AND PROCESS FOR THE PRODUCTION THEREOF

(71) Applicants: Peter Polcik, Reutte (AT); Conrad Polzer, Fussen (DE); Matthias Perl, Tannheim (AT); Stefan Schlichtherle, Ehrwald (AT); Georg Strauss, Munster (AT)

(72) Inventors: Peter Polcik, Reutte (AT); Conrad Polzer, Fussen (DE); Matthias Perl, Tannheim (AT); Stefan Schlichtherle, Ehrwald (AT); Georg Strauss, Munster (AT)

(73) Assignee: PLANSEE SE, REUTTE (AT)

(21) Appl. No.: 13/641,350

(22) PCT Filed: Apr. 12, 2011
(86) PCT No.: PCT/AT11/00175

§ 371 Date: Nov. 20, 2012

(30) Foreign Application Priority Data
Apr. 14, 2010 (AT) GM 239/2010

(51) Int. Cl. C23C 14/34; C23C 14/32

(52) U.S. Cl. CPC C23C 14/3414; C23C 14/325
USPC 204/298.12; 264/319; 204/298.41

(57) ABSTRACT

A coating source for physical vapor deposition has at least one component, which has been produced from at least one pulverulent starting material in a powder metallurgy production process and at least one ferromagnetic region embedded in the component. The at least one ferromagnetic region, is introduced into the component and fixedly connected to the component during the powder metallurgy production process.

The present invention relates to a coating source for physical vapor deposition and a method for producing such a coating source.

Methods of physical vapor deposition are used to a large extent in technology for producing greatly varying layers. The application extends from the production of wear-proof and corrosion-resistant coatings for greatly varying substrate materials to the production of coated material composites, in particular in the semiconductor and electronics industry. Because of this broad application spectrum, various coating materials must be deposited.

Various techniques are used in physical vapor deposition, e.g., vapor deposition, cathode sputtering (sputter deposition), or electric arc vapor deposition (cathodic arc deposition or arc source vapor deposition technology).

In the method of sputter deposition, a plasma is generated in a chamber by means of a working gas, e.g., argon. Ions of the working gas are accelerated toward a target formed from coating material and knock particles of the coating material out of the target, which pass into the vapor phase and are deposited therefrom on a substrate to be coated. Forming a magnetic field over the active surface of the target to assist the process is known in the method of sputter deposition. The magnetic field elevates the plasma density in proximity to the active surface of the target and therefore results in an increased ablation of the coating material. Such a method is referred to as magnetron cathode sputtering (magnetron sputter deposition).

EP 1 744 347 A1 describes a target for magnetron sputter deposition, in which—with the goal of allowing sputtering of a ferromagnetic coating material—a magnet is arranged in a rear side of the target to enlarge the magnetic field passing through the active surface of the target. Arranging the magnet in the target by pressing it in or by bonding by means of known bonding technologies in drilled holes is described.

The method of cathodic arc deposition fundamentally differs from the above-described method of sputter deposition. Cathodic arc deposition is used, inter alia, for carbide coatings of tools and machine parts and for layers in the decorative application field. In cathodic arc deposition, an arc discharge is utilized, which is ignited between the coating material provided as the target, as the cathode, and an anode. The resulting high current-low voltage arc (arc hereafter) generates itself via the free charge carriers of the cathode and a higher partial pressure, so that an arc discharge can be maintained even under high vacuum. Depending on the design of the technology used, the position of the arc moves either more or less randomly (so-called random arc technique) or in a controlled manner (so-called steered arc technique) over the surface of the cathode, a high energy introduction into the surface of the target occurring in a very small area (in so-called spots). This high energy introduction locally results in vaporization of the coating material at the surface of the target. The region of a spot consists of liquid droplets of the coating material, coating material vapor, and generated ions of the coating material. The target is only transferred into the molten state in very small areas and can therefore be operated in any location as a vapor deposition source with relatively high coating rate. The ionizing of the coating material vapor is of great significance for the resulting properties of the layer made of coating material deposited on the substrate to be coated. With coating materials having high vapor pressure, typically approximately 25% of the vapor particles are in the ionized state and typically between 50% and 100% of the vapor particles are in the ionized state with coating materials having low vapor pressure. Therefore, no additional ionization devices in the facility are required for reactive ion plating. The fundamental parameters in the technique of cathodic arc deposition are the arc voltage and the arc current, which are influenced by further parameters, such as the material of the target, a provided reactive gas, and the given working pressure in particular. Typical operating conditions in cathodic arc deposition are, for example, an arc voltage between 15 V and 30 V and an arc current between 50 A and 150 A.

In cathodic arc deposition, the speed of the movement of the arc on the surface of the target determines the quantity of the molten material in the corresponding spot. The lower this speed, the larger the quantity of coating material accelerated out of the spot toward the substrate to be coated. A low speed therefore results in undesired sprays or macroparticles in the layer growing on the substrate. The achieved speed of the movement of the arc is a function of the coating material of the target. A reduced electrical conductivity of the coating material results in a decrease of the speed of the arc. If the speed of the arc on the surface of the target is excessively low, i.e., there is an excessively long dwell time on one spot, local thermal overload of the target and strong contamination of the layer growing on the substrate with undesired sprays or macroparticles are the result. Premature unusability of the target can also occur because of macroscopic melted areas of the surface.

The speed of the position of the arc and therefore the spot size can be influenced by magnetic fields. The higher the magnetic field strength, the more rapidly the arc moves. In facilities for cathodic arc deposition, providing electromagnets or permanent magnets behind a cooled support for the target, in order to influence the speed of the arc, is known.

DE 43 29 155 A1 describes a magnetic field cathode for arc discharge vaporizers having a coil arrangement and a permanent magnet arranged in the target center to achieve a more uniform erosion of the target material.

It is the object of the present invention to provide a coating source for physical vapor deposition and a method for the production thereof, using which a stable coating process in magnetron sputter deposition or a good control of the arc speed in cathodic arc deposition is achieved, respectively, and simultaneously the best possible thermal coupling to a cooled support of the coating facility, efficient production of the coating source with few work steps, and an arrangement of ferromagnetic material in nearly arbitrary geometry spatially close to the active surface of a target are possible even with materials which can be mechanically processed only with difficulty or not at all, and the risk of the introduction of contaminants into the coating facility via the coating source is minimized.

This object is achieved by a coating source for physical vapor deposition according to claim 1. Advantageous refinements are specified in the dependent claims.

The coating source for physical vapor deposition has: at least one component manufactured in a powder-metallurgical production process from at least one powdered starting material and at least one ferromagnetic region embedded in the component. The at least one ferromagnetic region is introduced and integrated in the component during the powder-metallurgical production process.

One coherent or multiple ferromagnetic regions can be provided. Ferromagnetic is understood to mean that this region (or these regions) has a coefficient of magnetic permeability >>1. The at least one ferromagnetic region can be designed as a permanent magnet or one or more permanent-magnetic regions and/or one or more non-magnetized regions can be provided. The at least one ferromagnetic region can have ferromagnetic powder which is introduced in powder form during a production process for the coating source, for example. The at least one ferromagnetic region can, e.g., also alternatively or additionally have one or more macroscopic ferromagnetic bodies introduced during the production process. The at least one component of the coating source can be formed, e.g., by the actual target, i.e., the coating material to be vaporized of the coating source. The at least one component can, however, e.g., also be formed by a back plate, which is fixedly connected to the target, made of a different material for thermal coupling to a cooled support in a coating facility. In a configuration of the coating source in which the actual target is removably fastened on a mount, which is designed for the purpose of connecting the target to a cooled support of a coating facility, the at least one component can also, e.g., be formed by the mount. Ferromagnetic regions can be formed, e.g., both in the target and also in a back plate or both in the target and also in the mount, respectively. In all of these cases, the at least one ferromagnetic region is arranged in such a manner that it is arranged in operation between a cooled support of the coating facility and the active surface of the target. Because of this arrangement, a magnetic field geometry can be achieved which is active very close to the active surface of the target, so that in the surface-proximal region of the target, a high magnetic field density can be provided. A magnetic field system independent of the coating facility used is therefore provided, which can be adapted and optimized to the respective coating material and the applied processes. Furthermore, in this manner, defined regions of the surface of the target can be shielded in a selected manner. The danger of overheating and increased emission of sprays of the coating material resulting therefrom during cathodic arc deposition can be avoided.

In this context, embedded in the component means fixedly connected to the component. The at least one ferromagnetic region became introduced into the component during the powder-metallurgical production process and fixedly connected to the component, i.e., it has been processed together with it during the powder-metallurgical production process such that it is permanently connected to the remainder of the component.

Since the ferromagnetic region is directly embedded in the component of the coating source, it is located close to the active surface of the target in operation of the coating source and can therefore ensure a stable coating process during magnetron sputter deposition or a good control of the arc speed during cathodic arc deposition. The at least one ferromagnetic region can be pressed, forged, hot-isostatically pressed, rolled, hot pressed, and/or sintered together with the component. Since the at least one ferromagnetic region is introduced into the component during the powder-metallurgical production process and fixedly connected to the component by this process, it can be connected to the component without gaps and cavities, so that a good thermal conductivity to a cooled support of a coating facility is implemented. In particular, in this manner no cavities which obstruct an undisturbed heat flow from the target surface to a cooled support are formed in the component. Furthermore, through the introduction in the powder-metallurgical production process, ferromagnetic regions having nearly arbitrary geometries can be embedded and these can also be completely enclosed by the material of the component, for example. The introduction into the component can be performed independently of the material of the component, so that one or more ferromagnetic regions can also be arranged in components which can be mechanically reworked only with difficulty or not at all. Furthermore, the coating source having the at least one ferromagnetic region in at least one component can also be produced cost-effectively and with few production steps, since recesses for a ferromagnetic region do not have to be mechanically manufactured and the ferromagnetic region does not have to be introduced in a further step after a production of the component. Through the introduction and integration of the at least one ferromagnetic region during the powder-metallurgical production process, the coating source can also be provided in a form which is closed per se, in which no cavities are present, in which contaminants could possibly collect, which could result during a coating process in worsening of the vacuum or undesired contaminations of the growing layer. In particular the following alloys can be used as ferromagnetic materials: NdFeB, SmCo, AlNiCo, SrFe, BaFe, Fe, Co, and Ni.

According to one embodiment, the at least one ferromagnetic region has at least one region made of ferromagnetic material introduced in powder form in the powder-metallurgical production process. In this case, ferromagnetic regions having greatly varying geometries can be provided in the component in a simple manner. Furthermore, e.g., multiple ferromagnetic regions having different compositions of the ferromagnetic material can be provided in a simple manner, so that the magnetic field achieved on the active surface of the target can be shaped in a targeted manner. E.g., in a simple manner, at least one ferromagnetic region can also be provided with position-dependent variation of the composition of the ferromagnetic material. The at least one ferromagnetic region can also, e.g., exclusively have ferromagnetic material introduced in powder form. Particularly simple production is made possible in this case.

According to one embodiment, the at least one ferromagnetic region has at least one permanent-magnetic region. The permanent-magnetic region can be formed, e.g., by the introduction of a previously magnetized macroscopic body or it is also possible, e.g., to magnetize the region embedded in the component during or after the production of the component.

According to one embodiment, the at least one ferromagnetic region has at least one ferromagnetic body introduced in the powder-metallurgical production process. Through the introduction of one or more ferromagnetic macroscopic bodies, the achieved magnetic field can be influenced very precisely, in particular in the case of magnetized (permanent-magnetic) bodies. In particular, e.g., multiple permanent-magnetic bodies can be introduced with different orientation of the magnetization.

According to one embodiment, the coating source has a target and the at least one ferromagnetic region is arranged in the target. A target is understood in this context as the region of the coating source which is manufactured from the material used as the coating material, which is eroded during the application. In this embodiment, the at least one ferromagnetic region can be provided very close to the active surface of the target, so that even problematic coating materials can be vaporized in a controlled manner. This embodiment can also be used in particular where the target is coupled directly (without further intermediate structures) to a cooled support of a coating facility.

According to one embodiment, the coating source has a target and a back plate, which is fixedly connected to the target, for thermal coupling to a cooled support of a coating facility, and the at least one ferromagnetic region is arranged in the target and/or the back plate. In such an arrangement, the at least one ferromagnetic region can therefore be formed in the target, in the back plate, or in both. Furthermore, various ferromagnetic regions can be formed both in the target and also in the back plate. The embodiment having a target and a back plate fixedly connected to the target can be applied in particular if the coating material has a rather low thermal conductivity and therefore, because of the resulting overheating hazard, cannot be provided as a target having a large thickness, but a large overall height from a cooled support to the active surface of the target is required in the coating facility. The target and the back plate can be manufactured, e.g., by a production in a joint powder-metallurgical process from different materials. E.g., the target can be formed from TiAl optionally having further components (in particular Cr, B, C, or Si) and the back plate can be formed from Al or Cu. The materials of the target and the back plate can be layered one over another in powder form in the production process, for example, and subsequently jointly compressed and/or forged. However, it is also possible, for example, that the target and the back plate are fixedly connected to one another by bonding with indium or in a similar manner, for example.

According to one embodiment, the coating source has a target and a mount, which is removably connected to the target, for connecting the target to a cooled support of a coating facility, and the at least one ferromagnetic region is arranged in the mount. This arrangement can be used, e.g., if only relatively thin targets are expedient, but a relatively large overall height from a cooled support to the active surface of the target must be implemented in a coating facility. The target and the mount can be removably connected to one another, e.g., via a mechanical fastening. In this embodiment, the magnetic field can in turn be provided independently of the facility and in a target-specific manner through the arrangement of the at least one ferromagnetic region in the mount. The replaceable target can be provided cost-effectively with or without ferromagnetic regions.

According to one embodiment, the coating source is a magnetron sputter deposition coating source. In this case, the at least one ferromagnetic region in proximity to the active surface of a target can be used for controlling the sputtering process on the active surface in a targeted manner.

According to one embodiment, the coating source is a cathodic arc deposition coating source. In this case, the at least one ferromagnetic region in proximity to the active surface of a target can be used for the purpose of controlling the movement of the electric arc on the surface. Movement or ablation patterns can be set in a selective manner, a collapse of the arc in the middle of the coating source can be reduced or prevented in a selective manner, and a controlled magnetically induced displacement of the arc onto desired regions of the coating source can be caused.

The object is also achieved by a method for producing a coating source for physical vapor deposition according to Claim 10. Advantageous refinements are specified in the dependent claims.

The method has the following steps: placing at least one powdered starting material for at least one component of the coating source into a mold; introducing ferromagnetic powder and/or at least one ferromagnetic body into the mold, so that it is arranged in at least one region of the powdered starting material; and compacting the component thus formed. In this manner, the advantages described above with reference to the coating source are achieved. In particular, using the method, ferromagnetic regions can be implemented in proximity to an active surface of a target in a simple manner and with few method steps, even in the case of materials which can be mechanically processed only with difficulty or not at all. Therefore, one or more ferromagnetic regions can be embedded in the material of the component in a simple manner and with nearly arbitrary geometry, and it is also possible in a simple manner to completely enclose these regions, e.g., with the material. This is possible with greatly varying materials. The ferromagnetic region or regions can, e.g., again be arranged in a target and/or a back plate fixedly connected to the target and/or a mount. It is possible, e.g., to first place the powdered starting material for the component into the mold and subsequently the ferromagnetic powder or the at least one ferromagnetic body, respectively. However, it is also possible to first introduce the ferromagnetic powder or the at least one ferromagnetic body, respectively, into the mold and subsequently the powdered starting material. In addition to the compacting, shaping of the component formed can also be performed.

According to one embodiment, the introduction is performed at least in one region of the starting material, which forms a target in the coating source. According to a further embodiment, the introduction is performed at least in one region of the starting material which, in the coating source, forms a back plate, which is fixedly connected to a target, for thermal coupling to a cooled support of a coating facility. According to a further embodiment, the introduction is performed in a region of the starting material which, in the coating source, forms a mount, which is removably connected to a target, for connecting the target to a cooled support of a coating facility.

Further advantages and refinements result from the following description of exemplary embodiments with reference to the appended drawings.

FIG. 1 schematically shows a coating source according to a first embodiment in a top view

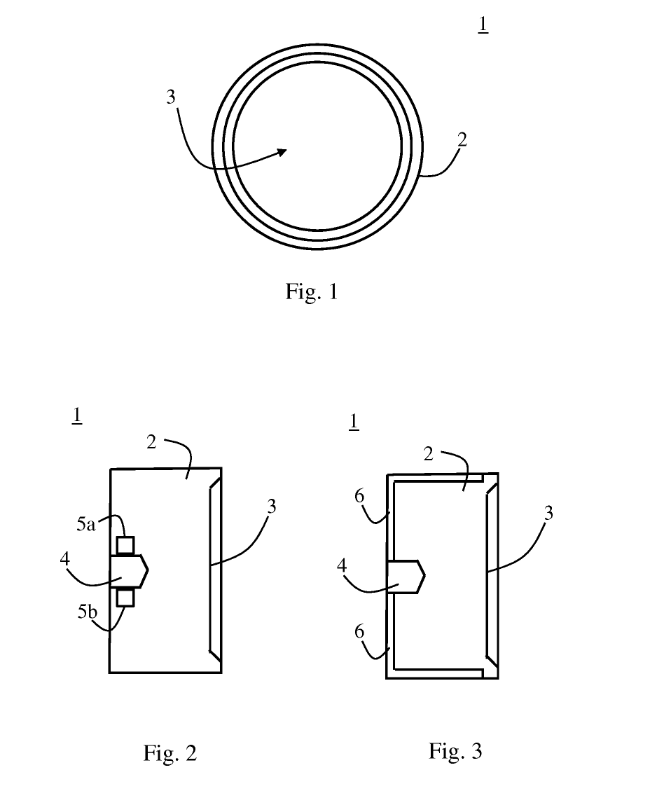

FIG. 2 schematically shows an example of a coating source according to the first embodiment in a lateral section

FIG. 3 schematically shows a second example of a coating source according to the first embodiment in a lateral section

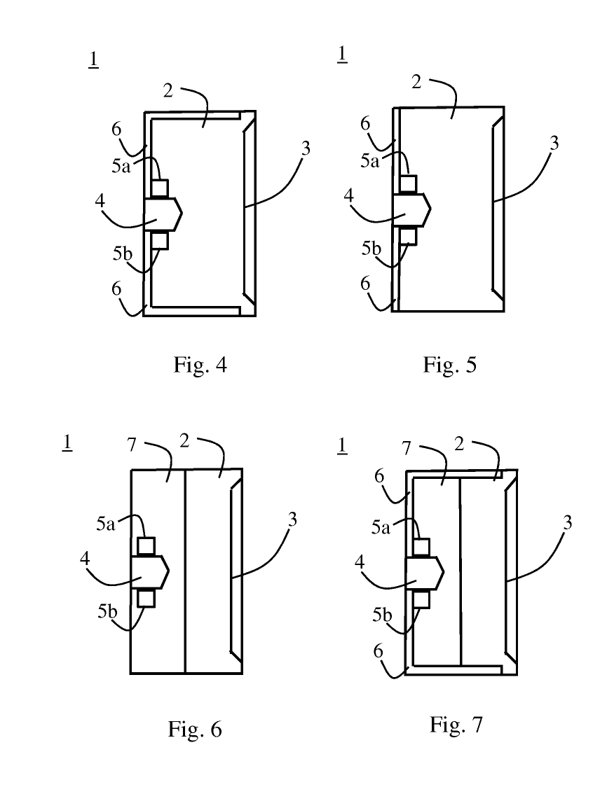

FIG. 4 schematically shows a third example of a coating source according to the first embodiment in a lateral section

FIG. 5 schematically shows a fourth example of a coating source according to the first embodiment in a lateral section

FIG. 6 schematically shows a first example of a coating source according to a second embodiment in a lateral section

FIG. 7 schematically shows a second example of a coating source according to the second embodiment in a lateral section

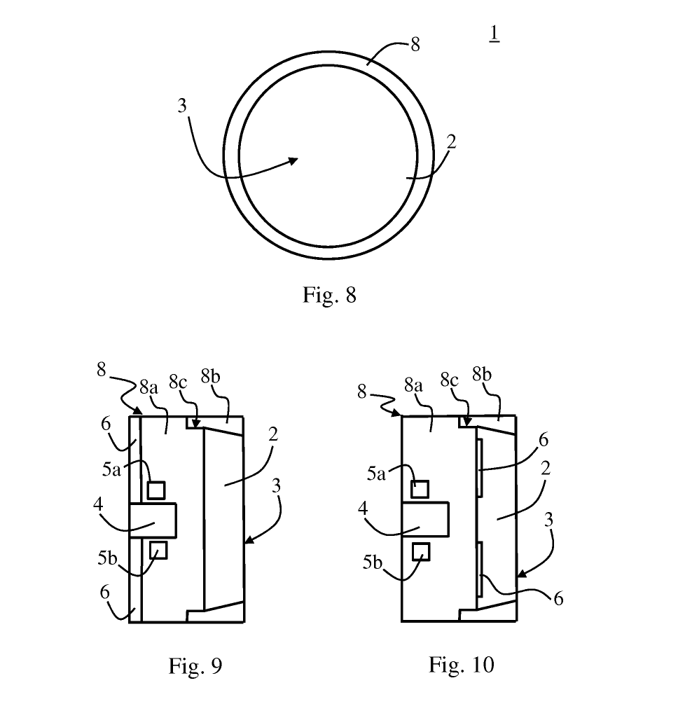

FIG. 8 schematically shows a coating source having a target and a mount in a top view

FIG. 9 schematically shows a coating source with mount in a lateral section

FIG. 10 schematically shows a further coating source with mount in a lateral section

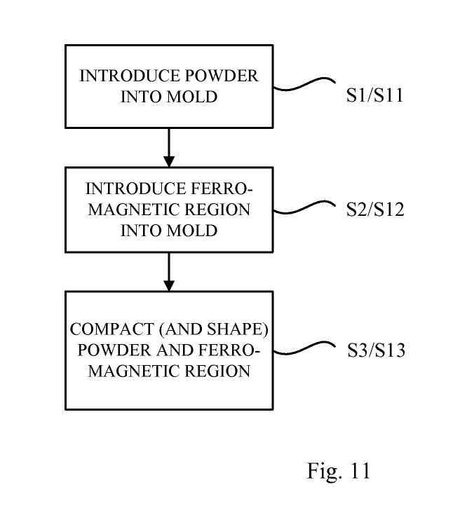

FIG. 11 shows a schematic block diagram to explain a production method of a coating source

### FIRST EMBODIMENT

A first embodiment is described hereafter with reference to FIG. 1 to FIG. 5. In the illustrated embodiment, the coating source -1- is formed by a target -2- for a method of cathodic arc deposition. The target -2- is designed in this embodiment to be fastened directly onto a cooled support of a coating facility. Although a coating source -1- having a circular cross section is shown in FIG. 1, other shapes, e.g., oval, rectangular, etc., are also possible. This also applies for the further embodiments and the modifications thereof described hereafter. Although only embodiments and modifications are described in the present case in which the coating source -1- is respectively designed for cathodic arc deposition, it is respectively also possible to design the coating source for magnetron sputter deposition.

The target -2- has an active surface -3-, on which the material of the target -2- is eroded during a coating process. In the illustrated embodiment, the target -2- has, in the rear side facing away from the active surface -3-, a bore -4- for fastening on a cooled support of a coating facility. However, it is also possible to provide another type of fastening on the cooled support. In the embodiment shown in FIG. 2, the coating source -1- is completely formed by the coating material to be vaporized during the coating method, so that the target -2- forms the single component of the coating source -1-. The target -2- is formed in a powder-metallurgical production process from at least one starting material. E.g., it can be formed from a pulverulent starting material or a mixture made of various pulverulent starting materials.

In the first embodiment, at least one ferromagnetic region is embedded in the material of the target -2-. In the example shown in FIG. 2, two ferromagnetic regions -5a- and -5b- are formed in the material of the target -2-. The ferromagnetic regions -5a- and -5b- are formed in the example of FIG. 2 by two macroscopic permanent-magnetic bodies, which are embedded in the material of the target -2-. The ferromagnetic regions -5a- and -5b- were introduced during the powder-metallurgical production process for producing the target -2- into the powdered starting material and became connected to the material of the target -2-. They were compacted and shaped jointly with the powdered starting material, so that they are permanently connected to the material of the target -2-. Although two such bodies are shown as examples in FIG. 2, only one such body or more than two such bodies can also be introduced. The introduced bodies can have arbitrary other shapes.

FIG. 3 shows a second example of a coating source -1- according to the first embodiment. The second example differs from the example described on the basis of FIG. 2 in that the at least one ferromagnetic region -6- is not formed by introduced macroscopic bodies, but rather by ferromagnetic powder introduced into the starting material of the target -2-. The ferromagnetic powder is introduced during the powder-metallurgical production process for producing the target -2- into the powdered starting material and is connected to the material of the target -2- as in the first example by joint processing. Although a specific yoke-like shape of the ferromagnetic region -6- is shown in FIG. 3, many other arrangements are also possible. A single ferromagnetic region -6- or a plurality of ferromagnetic regions can again be formed.

FIG. 4 shows a third example of a coating source -1- according to the first embodiment. In the third example, both ferromagnetic regions -5a- and -5b-, which are formed by introduced macroscopic bodies, and also a ferromagnetic region -6-, which is formed by introduced ferromagnetic powder, are provided. Therefore, this is a combination of the first example and the second example. FIG. 5 shows a further example, which differs from the example shown in FIG. 4 in the shape of the ferromagnetic region -6- formed by ferromagnetic powder.

In the first embodiment, the coating source -1- therefore has a target -2-, which is designed for the purpose of being directly connected to a support, which is to be cooled, of a coating facility. One or more ferromagnetic regions -5a-, -5b-, -6- are formed in the target -2-, which are respectively formed by ferromagnetic bodies or ferromagnetic powder introduced during the powder-metallurgical production process. The ferromagnetic regions can be designed as permanent magnets, e.g., through introduced permanent-magnetic bodies or by cooling down the ferromagnetic powder below the Curie temperature in an external magnetic field.

A method for producing a coating source -1- according to the first embodiment will be described hereafter with reference to FIG. 11.

In a step -S1-, powdered starting material (one or more powders) for the target -2- is introduced into a mold. In a step -S2-, the at least one ferromagnetic region -5a-, -5b-, and/or -6- is introduced into the powdered starting material. This can be performed, e.g., by introducing at least one macroscopic ferromagnetic body or by introducing ferromagnetic powder. In a step -S3-, the powdered starting material is compacted jointly with the introduced ferromagnetic region and optionally shaped.

This can be performed, e.g., by pressing under high pressure in a press and subsequent forging. Processing by rolling, hot-isostatic pressing (hipping), hot pressing, etc., for example, can also be performed. It is to be noted that method steps -S1- and -S2-, e.g., can also be carried out in the reverse sequence.

Although the ferromagnetic regions -5a-, -5b-, -6- are respectively located on an edge of the material of the target -2- in FIGS. 2 to 5, it is also possible, e.g., to form them enclosed on all sides by the material of the target -2-. For the case in which both ferromagnetic regions formed by introduced ferromagnetic powder and also ferromagnetic regions formed by introduced ferromagnetic bodies are provided, the regions formed by introduced powder can be formed in arbitrary arrangement to the regions formed by ferromagnetic bodies. In particular, e.g., the regions formed by introduced ferromagnetic powder can be formed closer to the active surface of the target or farther away therefrom than the regions formed by introduced ferromagnetic bodies.

### SECOND EMBODIMENT

A second embodiment is described hereafter with reference to FIG. 6 and FIG. 7. To avoid repetitions, only the differences from the first embodiment are described and the same reference signs are used for the corresponding components.

In the second embodiment, the coating source -1- has a target -2- having an active surface -3- and a back plate -7-, which is fixedly connected to the target -2-, as components. The back plate -7- is designed for the purpose of being fastened on a cooled support of a coating facility, which can be achieved, e.g., by a bore -4- shown as an example. The back plate -7- is designed for the purpose of providing good thermal coupling of the target -2- to the cooled support, in order to ensure good heat dissipation from the target -2-. In the exemplary embodiment, both the target -2- and also the back plate -7- are manufactured from powdered starting materials in a joint powder-metallurgical production process. E.g., the material of the target -2- can be a coating material having low thermal conductivity, e.g., TiₓAl_{y} optionally having further components, and the material of the back plate -7- can be a material having high thermal conductivity, e.g., Al or Cu. The fixed connection between the two components of the coating source -1-, the target -2- and the back plate -7-, can be caused, e.g., in that powdered starting material for the target -2- and powdered starting material for the back plate were layered one over another in a shared mold and compacted and subsequently optionally forged, hot-isostatically pressed, rolled, hot pressed, and/or sintered.

In the second embodiment, at least one ferromagnetic region is embedded in the target -2- and/or the back plate -7-. One or more ferromagnetic regions can be formed in the target -2-, one or more ferromagnetic regions can be formed in the back plate -7-, or respectively one or more ferromagnetic regions can be formed in both the target -2- and also in the back plate -7-. The individual ferromagnetic regions can again, e.g., be formed by introduced macroscopic bodies or by introduced ferromagnetic powder. They have been compacted and shaped jointly with the powdered starting material of the target -2- and/or the back plate -7-, so that they became permanently bonded to the material of the target -2- and/or the back plate -7-. One or more of the ferromagnetic regions can again be designed as permanent magnets. Two examples of these many various possible implementations are described hereafter.

In the example shown in FIG. 6, two ferromagnetic regions -5a- and -5b- are embedded in the back plate -7-. The two ferromagnetic regions -5a- and -5b- are formed by macroscopic permanent-magnetic bodies, which were introduced into the material of the back plate -7- during the powder-metallurgical production process in the starting material of the back plate -7- and became fixedly connected to the material of the back plate -7-. In the example shown in FIG. 7, a further ferromagnetic region -6- is additionally provided in the coating source -1-. The ferromagnetic region -6- is formed by ferromagnetic powder introduced in the powder-metallurgical production process into the respective powdered starting material of the target -2- and the back plate -7-.

A method for producing a coating source according to the second embodiment is described briefly hereafter with reference to FIG. 11.

In a step -S11- powdered starting material for the target -2- and powdered starting material for the back plate -7- are successively placed into a mold. E.g., first the starting material for the back plate -7- and subsequently the starting material for the target -2- can be introduced or vice versa. In a step -S12-, the at least one ferromagnetic region -5a-, -5b-, and/or -6- is formed by introducing ferromagnetic powder and/or at least one ferromagnetic body into at least one region of the powdered starting material for the target -2- and/or the back plate -7-. In a subsequent step -S13-, the powdered starting material is compacted and shaped jointly with the introduced ferromagnetic region. The steps -S11- and -S12- can also again be carried out in the reverse sequence in this case, for example.

### THIRD EMBODIMENT

A third embodiment is described hereafter with reference to FIGS. 8 to 10. Again, only the differences from the first and the second embodiments are described and the same reference signs are used for corresponding components.

In the third embodiment, the coating source -1- has a target -2- having an active surface -3- and a mount -8- for the target -2- as components. The mount -8- is designed for the purpose of removably receiving the target -2- and fastening it on a cooled support of a coating facility. The mount -8- is designed for the purpose of ensuring good thermal coupling of the target -2- to the cooled support. The connection to the cooled support can again be achieved, e.g., by a bore -4- shown as an example. In the embodiment shown in FIG. 9, the mount -8- has a first mount element -8a- and a second mount element -8b-, which are designed for the purpose of holding the target -2- in a formfitting manner. The first mount element -8a- and the second mount element -8b- can be removably connected to one another, e.g., via a thread -8c-, to enclose the target -2- in a formfitting manner.

In the third embodiment, at least one ferromagnetic region is embedded in the mount -8- and/or the target -2-. One or more ferromagnetic regions can be formed in the target -2-, one or more ferromagnetic regions can be formed in the mount -8-, or respectively one or more ferromagnetic regions can be formed both in the target -2- and also in the mount -8-. The individual ferromagnetic regions can again, e.g., be formed by introduced macroscopic bodies or by introduced ferromagnetic powder. They have been compressed and shaped jointly with the powdered starting material of the target -2- and/or powdered starting material of the back plate -8-, so that they are permanently bonded to the material of the target -2- and/or the mount -8-. One or more of the ferromagnetic regions can again be designed as permanent magnets. Two examples of these many various possible implementations are again described hereafter.

In the example shown in FIG. 9, both two ferromagnetic regions -5a- and -5b-, which are formed by embedded macroscopic permanent-magnetic bodies, and also one ferromagnetic region -6-, which is formed by ferromagnetic powder introduced in powder form in the powder-metallurgical production process for the mount -8-, are provided in the mount -8-. In this example, no ferromagnetic region is provided in the target -2-. In the further example shown in FIG. 10, two ferromagnetic regions -5a- and -5b-, which are formed by embedded macroscopic permanent-magnetic bodies, are provided in the mount -8-, and a further ferromagnetic region -6-, which is formed by ferromagnetic powder introduced in powder form in the powder-metallurgical production process for the target -2-, is provided in the target -2-.

During a production method for a coating source -1-, in one step, powdered starting material for the mount -8- and/or the target -2- is filled into a mold. In a further step, the at least one ferromagnetic region -5a-, -5b-, and/or -6- is formed by introducing ferromagnetic powder and/or at least one ferromagnetic body into at least one region of the powdered starting material. In a subsequent step, the powdered starting material is compacted and shaped jointly with the introduced ferromagnetic region.

Thus, embodiments have been described, using which it is possible in each case to provide a very high magnetic field density on the surface of the target of a coating source. In the case of cathodic arc deposition, in this manner the ignition properties and the stability of the arc during a coating process are substantially improved. With metallic targets, a reduction of the emission of sprays and droplets is achieved in this manner. With targets made of metal-ceramic material or ceramic material, because of the higher achieved speed in the movement of the electric arc and the possibility of steering the movement and therefore the erosion of the coating material in desired paths, the local energy introduction in the spot is decreased and disadvantages because of low electrical conductivity and low thermal shock resistance of the target material are compensated for. The introduced ferromagnetic or magnetic components can be arranged in such a manner that the erosion procedure or the erosion profile of the coating material can be controlled. Furthermore, direct deposition of ferromagnetic coating materials by means of cathodic arc deposition is also made possible using the described arrangements.

The magnetic region or regions can be optimized, e.g., so that in cooperation with external magnetic fields provided in the coating facility in the surface-proximal region of the target, the desired magnetic fields are set with high precision. A selective attenuation and/or amplification of facility-side magnetic fields with local resolution can be provided. The magnetic regions can, e.g., also be formed in such a manner that specific regions are shielded for the coating process, so that no noticeable erosion occurs therein. Furthermore, specific regions of the target can be protected from poisoning through the described embodiment, in that, e.g., through selective formation of the resulting magnetic fields, undesired coating of the target with, e.g., ceramic nitride or oxide layers is avoided. In a coating source for a cathodic arc deposition process, the movement paths of the arc on the active surface of the target can be predefined. This allows, e.g., the use of segmented targets, which have different material compositions in various regions, for depositing layers having desired chemical composition.

The embodiment of the coating source with target and fixedly connected back plate or with target and mount, respectively, can particularly also be used if the target consists of a material which can be machined only with difficulty or not at all, e.g., a ceramic, so that subsequent introduction of threaded bores or clamping steps into the target material is not possible.

1-13. (canceled)

14. A coating source for physical vapor deposition, comprising:
at least one component formed in a powder-metallurgical production process from at least one pulverulent starting material; and
at least one ferromagnetic region embedded in said at least one component, said at least one ferromagnetic region having been introduced into said at least one component and fixedly connected to said at least one component in the powder-metallurgical production process.

15. The coating source according to claim 14, wherein said at least one ferromagnetic region includes at least one region made of ferromagnetic material introduced in powder form in the powder-metallurgical production process.

16. The coating source according to claim 14, wherein said at least one ferromagnetic region comprises at least one permanent-magnetic region.

17. The coating source according to claim 14, wherein said at least one ferromagnetic region comprises at least one ferromagnetic body introduced in the powder-metallurgical production process.

18. The coating source according to claim 14, wherein the coating source comprises a target and the at least one ferromagnetic region is arranged in the target.

19. The coating source according to claim 14, comprising a target and a back plate fixedly connected to said target and configured for thermal coupling to a cooled support of a coating facility, and said at least one ferromagnetic region being arranged in one or both of said target or said back plate.

20. The coating source according to claim 14, comprising a target and a mount removably connected to said target and configured for connecting said target to a cooled support of a coating facility, and said at least one ferromagnetic region being arranged in said mount.

21. The coating source according to claim 14, configured as a magnetron sputter deposition coating source.

22. The coating source according to claim 14, configured as a cathodic arc deposition coating source.

23. A method for producing a coating source for physical vapor deposition, the method comprising the following steps:
placing pulverulent starting material for at least one component of the coating source into a mold;
introducing ferromagnetic powder and/or at least one ferromagnetic body into the mold, for placing the ferromagnetic powder and/or the at least one ferromagnetic body in at least one region of the pulverulent starting material; and
compacting the component thus formed.

24. The method according to claim 23, wherein the introducing step comprises introducing the ferromagnetic powder and/or the at least one ferromagnetic body in a region of the starting material that forms a target in the coating source.

25. The method according to claim 23, wherein the introducing step comprises introducing the ferromagnetic powder and/or the at least one ferromagnetic body in a region of the starting material which, in the coating source, forms a back plate fixedly connected to a target, for thermal coupling to a cooled support of a coating facility.

26. The method according to claim 23, wherein the introducing step comprises introducing the ferromagnetic powder and/or the at least one ferromagnetic body in a region of the starting material which, in the coating source, forms a mount, which is removably connected to a target, for connecting the target to a cooled support of a coating facility.
